(19) United States
(12) Patent Application Publication
(10) Pub. No.: US 2026/0005688 A1
(43) Pub. Date: Jan. 1, 2026

(54) ISOLATED GATE DRIVE CIRCUIT AND DRIVER

(71) Applicant: Trex Technologies Corporation, Guangzhou City (CN)

(72) Inventors: Xin DONG, Guangzhou City (CN); Min Jennifer FANG, Guangzhou City (CN)

(21) Appl. No.: 19/019,041

(22) Filed: Jan. 13, 2025

(30) Foreign Application Priority Data
Jun. 27, 2024 (CN) 202410841105.3

(51) Int. Cl. H03K 17/14; H03K 5/1534; H03K 7/08

(52) U.S. Cl. CPC H03K 17/145; H03K 5/1534; H03K 7/08

(57) ABSTRACT

An isolated gate drive circuit and a driver, the isolated gate drive circuit includes signal restoration module, modulation module with first terminal and second terminal, high-pass filter module, and falling edge monitoring module; first pulse signal output from the first and second terminals are rail-to-rail differential pulse signals; When the isolated gate drive circuit restores the pulse width modulation signal, the isolated gate drive circuit monitors the first pulse signals output from the first and second terminals of the modulation module. When the pulse signal in the first pulse signal output from the first terminal or the second terminal of the modulation module is in a falling edge state, the falling edge monitoring module outputs a third pulse signal to the signal restoration module, the signal restoration module can quickly output the restored the pulse width modulation signal, improving the reliability of the isolated gate drive circuit.

### CROSS-REFERENCE TO RELATED APPLICATIONS

This application claims priority to Chinese Patent Application No. 202410841105.3, filed on Jun. 27, 2024, the content of all of which is incorporated herein by reference.

### FIELD OF THE DISCLOSURE

This application relates to the technical field of drive circuits, in particular to an isolated gate drive circuit and a driver.

### BACKGROUND

Drive circuits are an essential component of modern power electronic systems. Among them, isolated gate drive circuit isolates electrically a primary side down-voltage circuit from a secondary side high-voltage circuit by forming a separate ground reference to protect safety of electricity. Therefore, isolated gate drive circuits are widely used.

In applications of isolated gate drive circuits, propagation delay is a critical parameter that can impact the loss and safety of high-frequency systems. Especially in the isolated gate drive circuit utilizing capacitive isolation technology, there may be issues during signal demodulation on the secondary side of the high-voltage circuit, due to reasons such as insufficient signal gain in the demodulation circuit or excessive parasitic capacitance, in a first falling edge of the demodulated signal output by the demodulation circuit within a first cycle, resulting in that the isolated gate drive circuit fails to output a restored PWM (Pulse Width Modulation) signal, leading to a delayed restored PWM signal and reduced reliability.

Therefore, the prior technology is subject to improvement and development.

### BRIEF SUMMARY OF THE DISCLOSURE

In view of the above deficiencies of the prior art, the present disclosure provides an isolated gate drive circuit and a driver to solve the problem of the prior art in which, due to insufficient signal gain in the demodulation circuit or excessive parasitic capacitance, the isolated gate drive circuit fails to output a restored pulse width modulation signal in the first falling edge within the first cycle of the demodulated signal. This results in a delay in the output of the restored pulse width modulation signal and reduces the reliability of the circuit.

The technical solutions adopted by the present disclosure to solve the technical problem are to provide an isolated gate drive circuit including:
a modulation module, includes a first terminal and a second terminal, where the first terminal is configured to output a first pulse signal, and the second terminal is configured to output a first pulse signal, the first pulse signal output from the first terminal and the first pulse signal output from the second terminal are rail-to-rail differential pulse signals;
a high-pass filter module, connected to the first terminal and the second terminal respectively, and configured to filter the first pulse signal output from the first terminal and the second terminal, and then outputs a second pulse signal;
a falling edge monitoring module, connected to the first terminal and the second terminal respectively, and configured to output a third pulse signal when the first pulse signal output from the first terminal or the first pulse signal output from the second terminal is in a falling edge state;
a signal restoration module, connected to the high-pass filter module and the falling edge monitoring module respectively, and configured to quickly output a restored pulse width modulation signal based on the second pulse signal or the third pulse signal.

Further, the signal restoration module includes a first current mirror, a second current mirror, a first differential pair transistor, a second differential pair transistor, a first Schmitt trigger, a first inverter, and a second inverter;
the first current mirror includes a third terminal, a fourth terminal, and a fifth terminal, the third terminal is connected to a first current, and the fourth terminal is connected to a supply voltage;
the second current mirror includes a sixth terminal, a seventh terminal, and an eighth terminal, the sixth terminal is connected to a second current, and the seventh terminal is grounded;
the first differential pair transistor includes a ninth terminal, a tenth terminal, an eleventh terminal, and a twelfth terminal, the ninth terminal is connected to the fifth terminal, the tenth terminal is connected to the eighth terminal, the eleventh terminal is connected to the high-pass filter module, and the twelfth terminal is connected to the high-pass filter module;
the second differential pair transistor includes a thirteenth terminal, a fourteenth terminal, a fifteenth terminal, and a sixteenth terminal, the fourteenth terminal is grounded, the fifteenth terminal is connected to the falling edge monitoring module, and the sixteenth terminal is connected to the falling edge monitoring module;
an input terminal of the first Schmitt trigger is connected to the connection path between the fifth terminal and the ninth terminal, and the input terminal is also connected to the thirteenth terminal, the output terminal of the first Schmitt trigger is connected to the input terminal of the first inverter, the output terminal of the first inverter is connected to the input terminal of the second inverter, and the output terminal of the second inverter outputs the restored pulse width modulation signal.

Further, the first current mirror includes a first MOSFET and a second MOSFET, the drain of the first MOSFET is commonly connected to the drain of the second MOSFET, a source of the first MOSFET is connected to the gate of the first MOSFET, and the gate of the first MOSFET is also connected to the gate of the second MOSFET, the source of the first MOSFET serves as the third terminal, a connection node between the drain of the first MOSFET and the drain of the second MOSFET serves as the fourth terminal, and the source of the second MOSFET serves as the fifth terminal;
the second current mirror includes a third MOSFET and a fourth MOSFET, the source of the third MOSFET is connected to the source of the fourth MOSFET, the gate of the third MOSFET is connected to the gate of the fourth MOSFET, and the gate of the third MOSFET is also connected to the source of the third MOSFET, the drain of the third MOSFET serves as the sixth terminal, the connection node between the source of the third MOSFET and the source of the fourth MOSFET serves as the seventh terminal, and the drain of the fourth MOSFET serves as the eighth terminal.

Further, the first differential pair transistor includes a fifth MOSFET and a sixth MOSFET;
the drain of the fifth MOSFET is connected to the drain of the sixth MOSFET, the source of the fifth MOSFET is connected to the source of the sixth MOSFET, the connection node between the drain of the fifth MOSFET and the drain of the sixth MOSFET serves as the ninth terminal, the connection node between the source of the fifth MOSFET and the source of the sixth MOSFET serves as the tenth terminal, the gate of the fifth MOSFET serves as the eleventh terminal, and the gate of the sixth MOSFET serves as the twelfth terminal.

Further, the second differential pair transistor includes a seventh MOSFET and an eighth MOSFET;
the drain of the seventh MOSFET is connected to the drain of the eighth MOSFET, the source of the seventh MOSFET is connected to the source of the eighth MOSFET, the connection node between the drain of the seventh MOSFET and the drain of the eighth MOSFET serves as the thirteenth terminal, the connection node between the source of the seventh MOSFET and the source of the eighth MOSFET serves as the fourteenth terminal, the gate of the seventh MOSFET serves as the fifteenth terminal, and the gate of the eighth MOSFET serves as the sixteenth terminal.

Further, the falling edge monitoring module includes:
two first monitoring units are provided, one of the first monitoring units is respectively connected to the first terminal and the signal restoration module, and the other first monitoring unit is respectively connected to the second terminal and the signal restoration module;

When the first pulse signal output from the first terminal is in a falling edge state, the first monitoring unit connected to the first terminal is configured to output a third pulse signal to the signal restoration module; and when the first pulse signal output from the second terminal is in a falling edge state, the first monitoring unit connected to the second terminal is configured to output a third pulse signal to the signal restoration module.

Further, the first monitoring unit includes a third current mirror, a ninth MOSFET, a tenth MOSFET, a first capacitor, a second Schmitt trigger, a first NAND gate, a third inverter, a fourth inverter, and a fifth inverter;
the third current mirror including a seventeenth terminal, an eighteenth terminal, and a nineteenth terminal, the seventeenth terminal is connected to a second current, and the eighteenth terminal is connected to a supply voltage;
the drain of the ninth MOSFET is connected to the nineteenth terminal, the gate of the ninth MOSFET, the gate of the tenth MOSFET, and the input terminal of the third inverter are commonly connected, the source of the ninth MOSFET is connected to the drain of the tenth MOSFET, the source of the tenth MOSFET is grounded, and the output terminal of the third inverter is connected to the first input terminal of the first NAND gate;
the input terminal of the second Schmitt trigger is connected to the connection path between the source of the ninth MOSFET and the drain of the tenth MOSFET, one terminal of the first capacitor is connected to the input terminal of the second Schmitt trigger, and the other terminal of the first capacitor is grounded, and the output terminal of the second Schmitt trigger is connected to the input terminal of the fourth inverter, the output terminal of the fourth inverter is connected to the second input terminal of the first NAND gate, and the output terminal of the first NAND gate is connected to the input terminal of the fifth inverter;
the common connection node of the gate of the ninth MOSFET, the gate of the tenth MOSFET, and the input terminal of the third inverter is configured for receiving the first pulse signal output from the modulation module, and the output terminal of the fifth inverter is configured to output the third pulse signal to the signal restoration module.

Further, the third current mirror includes: an eleventh MOSFET and a twelfth MOSFET;
the drain of the eleventh MOSFET is connected to the drain of the twelfth MOSFET, the gate of the eleventh MOSFET is connected to the gate of the twelfth MOSFET, and the gate of the eleventh MOSFET is also connected to the source of the eleventh MOSFET, the source of the eleventh MOSFET serves as the seventeenth terminal, the connection node between the drain of the eleventh MOSFET and the drain of the twelfth MOSFET serves as the eighteenth terminal, and the source of the twelfth MOSFET serves as the nineteenth terminal.

Further, the modulation module includes: a second NAND gate, a sixth inverter, a seventh inverter, a second capacitor, a third capacitor, and a first comparator with dual outputs;
the first input terminal of the second NAND gate is configured to receive the pulse width modulation signal, the second input terminal of the second NAND gate is configured to receive the oscillation signal, and the output terminal of the second NAND gate is connected to the input terminal of the sixth inverter and the input terminal of the seventh inverter respectively;
the output terminal of the sixth inverter is connected to one terminal of the second capacitor, and the output terminal of the seventh inverter is connected to one terminal of the third capacitor;
the first input terminal of the first comparator is connected to the other terminal of the second capacitor, and the second input terminal of the first comparator is connected to the other terminal of the third capacitor, the first output terminal of the first comparator serves as the first terminal, and the second output terminal of the first comparator serves as the second terminal.

The present disclosure further provides a driver including a printed circuit board and the isolated gate drive circuit as described above, the isolated gate drive circuit is mounted on the printed circuit board.

The beneficial effects of the present disclosure include:
the present disclosure discloses an isolated gate drive circuit and a driver. The isolated gate drive circuit includes:
a modulation module, including a first terminal and a second terminal; the first terminal is configured to output a first pulse signal, and the second terminal is configured to output a first pulse signal, the first pulse signal output from the first terminal and the first pulse signal output from the second terminal are rail-to-rail differential pulse signals; a high-pass filter module, connected to the first terminal and the second terminal respectively, and the high-pass filter module is configured to filter the first pulse signals output from the first terminal and the second terminal, and then output a second pulse signal; a falling edge monitoring module, connected to the first terminal and the second terminal respectively, and the falling edge monitoring module is configured to output a third pulse signal when the first pulse signal output from the first terminal or the first pulse signal output from the second terminal is in a falling edge state; a signal restoration module, connected to the high-pass filter module and the falling edge monitoring module respectively, and the signal restoration module is configured to quickly output a restored pulse width modulation signal based on the second pulse signal or the third pulse signal. In the present disclosure, when the isolated gate drive circuit restores the pulse width modulation signal, the isolated gate drive circuit also monitors the first pulse signals output from the first terminal and the second terminal of the modulation module by using the falling edge monitoring module. When the first pulse signal from the first terminal or the second terminal of the modulation module is in a falling edge state, the falling edge monitoring module outputs a third pulse signal to the signal restoration module, enabling the signal restoration module to quickly output the restored pulse width modulation signal. As can be seen, in the first falling edge of the first pulse signal within the first cycle output by the modulation module, the falling edge monitoring module can output a third pulse signal to the signal restoration module, enabling the signal restoration module to quickly output the restored pulse width modulation signal in the first falling edge of the first pulse signal within the first cycle output by the modulation module, thereby improving reliability of the isolated gate drive circuit.

### BRIEF DESCRIPTION OF THE DRAWINGS

In order to more clearly illustrate the technical solutions of the embodiments of the present disclosure or the prior art, the following is a simple introduction to the drawings used in the description of the embodiments or the prior art, obviously, the drawings described below are merely some embodiments of the present disclosure, for those skilled in the art, other drawings can be obtained based on these drawings without inventive effort.

FIG. 1 is a schematic structural diagram of an isolated gate drive circuit in the prior art.

FIG. 2 is a waveform diagram output by different nodes of the isolated gate drive circuit in the prior art.

FIG. 3 is a schematic structural diagram of an isolated gate drive circuit in the present disclosure.

FIG. 4 is a schematic structural diagram of a signal restoration module in one embodiment.

FIG. 5 is a schematic structural diagram of a first monitoring unit in one embodiment.

FIG. 6 is a waveform diagram output by different nodes of the isolated gate drive circuit in the present disclosure.

### DETAILED DESCRIPTION OF EMBODIMENTS

In order to have a clearer understanding of the technical features, purposes and effects of the present disclosure, specific embodiments of the present disclosure are described in detail with reference to the accompanying drawings. In the following description, it should be understood that terms such as “front”, “rear”, “upper”, “downer”, “left”, “right”, “longitudinal”, “transverse”, “vertical”, “horizontal”, “top”, “bottom”, “inner”, “outer”, “head”, “tail”, etc., indicate that the indicated orientation or positional relationship is based on the orientation or positional relationship shown in the accompanying drawings, constructed and operated in a particular orientation, only for the purpose of facilitating the description of the present technical solutions, and does not indicate that the indicated devices or element must have a particular orientation or positional relationship, the description is provided merely for the convenience of explaining the technical solutions and does not indicate that the devices or element must have a specific orientation; therefore, it should not be construed as a limitation on the present disclosure.

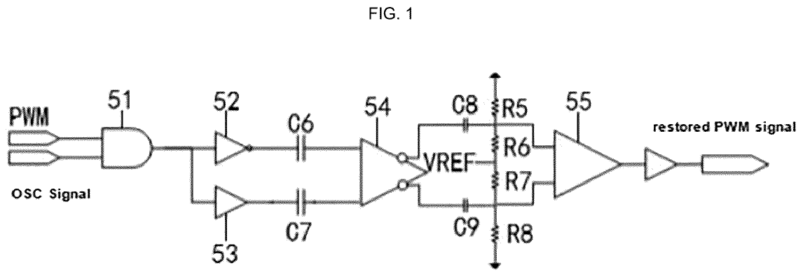

As shown in FIG. 1, a prior commonly used isolated gate drive circuit. In the isolated gate drive circuit shown in FIG. 1, a PWM (pulse width modulation) signal is input to a first input terminal of a third NAND gate 51, and an oscillation signal from the high-frequency oscillator (OSC) is input to a second input terminal of the third NAND gate 51, the output signal from the third NAND gate 51 is passed through an eighth inverter 52 and an ninth inverter 53 to output a pair of differential signals, the pair of differential signals is then output as a pair of narrow pulse signals through a sixth capacitor C6 and a seventh capacitor C7 (the sixth capacitor C6 and the seventh capacitor C7 are isolation capacitors), the pair of narrow pulse signals is then input to a second comparator 54, which outputs a pair of rail-to-rail differential pulse signals, the rail-to-rail differential pulse signals are filtered and then outputs as a pulse signal to a third comparator 55, which outputs the restored pulse width modulation signal.

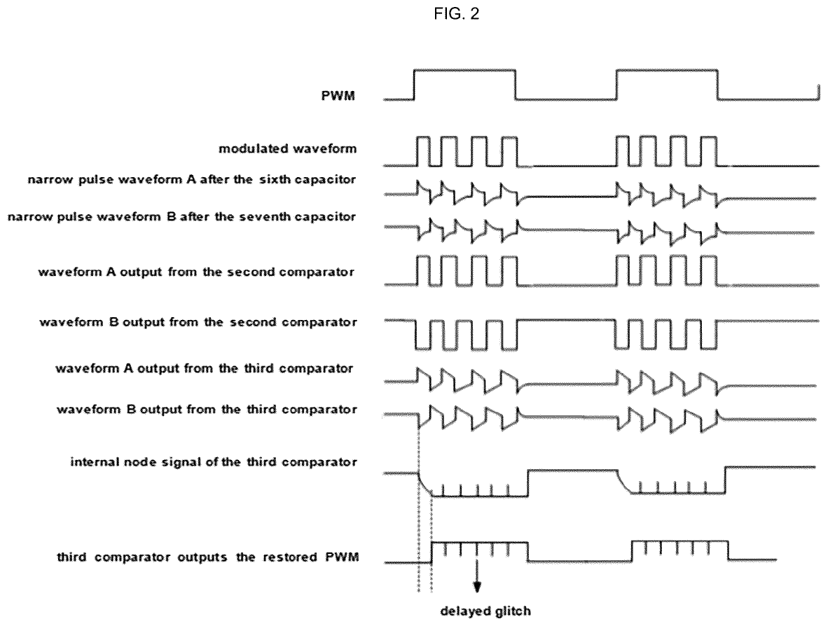

FIG. 2 is a signal flow diagram captured by an isolated gate drive circuit in the prior art. As shown in FIG. 2, when the third comparator 55 outputs the restored pulse width modulation signal, there is no output of the restored pulse width modulation signal in a first falling edge within a first cycle, which resulted in an output delay of the restored pulse width modulation signal, reducing reliability of the isolated gate drive circuit.

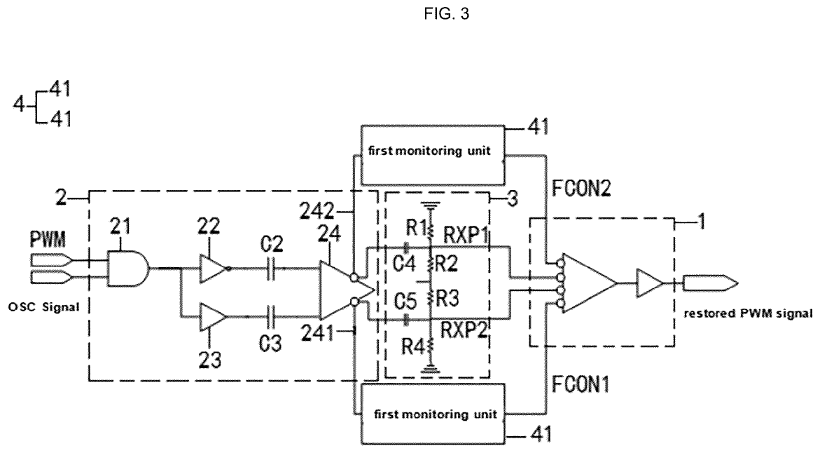

Due to the above problems, the present disclosure provides an isolated gate drive circuit. As shown in FIG. 3, the isolated gate drive circuit includes a signal restoration module 1, a modulation module 2, a high-pass filter module 3, and a falling edge monitoring module 4.

The modulation module 2 includes a first terminal 241 and a second terminal 242. The first terminal 241 is configured to output a first pulse signal, and the second terminal 242 is configured to output a first pulse signal. The first pulse signal output by the first terminal 241 and the first pulse signal output by the second terminal 242 are rail-to-rail differential pulse signals. The high-pass filter module 3 is respectively connected to both the first terminal 241 and the second terminal 242. The high-pass filter module 3 is configured to filter the first pulse signals output by the first terminal 241 and the second terminal 242, then output the second pulse signal. The falling edge monitoring module 4 is respectively connected to both the first terminal 241 and the second terminal 242, and the falling edge monitoring module 4 is configured to output a third pulse signal when the pulse signal from the first terminal 241 or the second terminal 242 is in a falling edge state. The signal restoration module 1 is respectively connected to both the high-pass filter module 3 and the falling edge monitoring module 4, and is configured to output a restored PWM signal based on the second pulse signal or the third pulse signal.

In the embodiment, when the isolated gate drive circuit outputs the restored pulse width modulation signal, the isolated gate drive circuit also monitors the first pulse signals output from the first terminal 241 and the second terminal 242 of the modulation module 2 by the falling edge monitoring module 4. When the first pulse signal from either the first terminal 241 or the second terminal 242 of the modulation module 2 is in a falling edge state, the falling edge monitoring module 4 outputs a third pulse signal to the signal restoration module 1, enabling the signal restoration module 1 to quickly output the restored PWM signal.

As can be seen, when the modulation module 2 outputs the first pulse signal in a first cycle, the falling edge monitoring module 4 can output a pulse signal to the signal restoration module 1 in the first falling edge of the pulse signal, and enables the signal restoration module 1 to quickly outputs the restored pulse width modulation signal in the first falling edge of the first pulse signal output from the modulation module 2 in the first cycle, thereby improving the reliability of the isolated gate drive circuit.

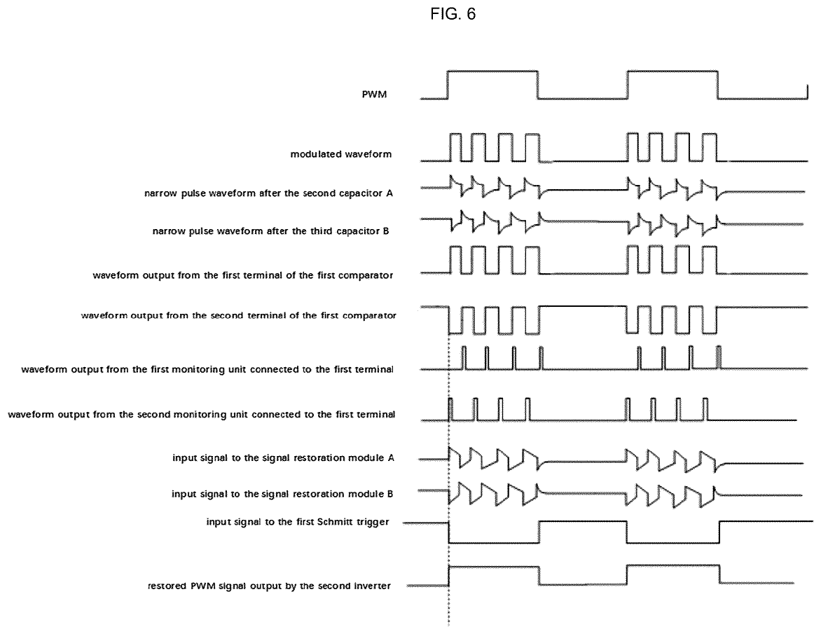

FIG. 6 shows a waveform diagram output from different nodes of the isolated gate drive circuit. By comparing FIG. 6 with FIG. 2, can be seen that the isolated gate drive circuit of the present disclosure eliminates the delay in the output of the restored pulse width modulation signal in the first falling edge within the first cycle of the demodulated signal, caused by issues such as insufficient signal gain in the demodulation circuit or excessive parasitic capacitance.

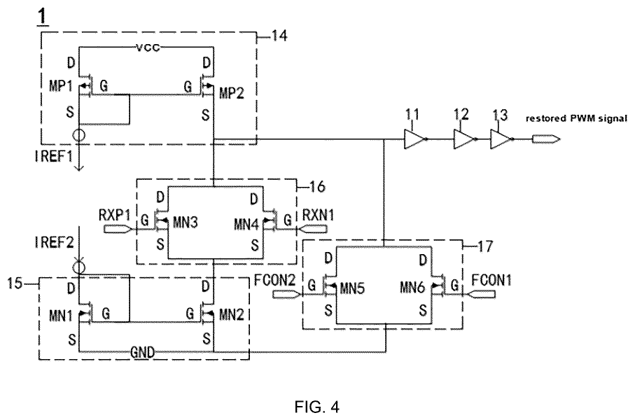

In some embodiments, as shown in FIG. 4, the signal restoration module 1 can include a first current mirror 14, a second current mirror 15, a first differential pair transistor 16, a second differential pair transistor 17, a first Schmitt trigger 11, a first inverter 12, and a second inverter 13.

The first current mirror 14 includes a third terminal, a fourth terminal, and a fifth terminal, where the third terminal is connected to the first current IREF1 and the fourth terminal is connected to the supply voltage VCC; the second current mirror 15 includes a sixth terminal, a seventh terminal, and an eighth terminal, where the sixth terminal is connected to the second current and the seventh terminal is grounded; the first differential pair transistor 16 including a ninth terminal, a tenth terminal, an eleventh terminal, and a twelfth terminal, where the ninth terminal is connected to the fifth terminal, the tenth terminal is connected to the eighth terminal, and the eleventh and twelfth terminals are connected to the high-pass filter module 3; the second differential pair transistor 17 including a thirteenth terminal, a fourteenth terminal, a fifteenth terminal, and a sixteenth terminal, where the fourteenth terminal is grounded, and the fifteenth and sixteenth terminals are connected to the falling edge monitoring module 4; the input terminal of the first Schmitt trigger 11 connects to the fifth terminal and the ninth terminal and is also connected to the thirteenth terminal. The output terminal of the first Schmitt trigger 11 is connected to the input terminal of the first inverter 12, the output terminal of the first inverter 12 is connected to the input terminal of the second inverter 13, and the output terminal of the second inverter 13 outputs the restored pulse width modulation signal.

When an input terminal of the first Schmitt trigger 11 is pulled down, the output terminal of the second inverter 13 outputs the restored pulse width modulation signal, and when the input terminal of the first Schmitt trigger 11 is pulled down, when any of the transistors in the first differential pair transistor 16 or any of the transistors in the second differential pair transistor 17 are conducting, the input of the first Schmitt trigger 11 is pulled down, and the output terminal of the second inverter 13 outputs a restored pulse width modulation signal.

In the embodiment, when the first pulse signal output from the first terminal 241 or the second terminal 242 of the modulation module 2 is in a falling edge state, the falling edge monitoring module 4 outputs a third pulse signal to the second differential pair transistor 17, causing at least one transistor in the second differential pair transistor 17 to conduct, thereby pulling the input terminal of the first Schmitt trigger 11 down, resulting in the output terminal of the second inverter 13 outputting the restored pulse width modulation signal.

Furthermore, as shown in FIG. 4, the first current mirror 14 includes a first Metal-Oxide-Semiconductor Field-Effect Transistor (MOSFET) MP1 and a second MOSFET MP2. A drain of the first MOSFET MP1 is commonly connected to the drain of the second MOSFET MP2, the source of the first MOSFET MP1 is connected to the gate, and the gate of the first MOSFET MP1 is also connected to the gate of the second MOSFET MP2. The source of the first MOSFET serves as the third terminal, a connection node between the drain of the first MOSFET and the drain of the second MOSFET serves as the fourth terminal, and the source of the second MOSFET serves as the fifth terminal.

The second current mirror 15 includes a third MOSFET MN1 and a fourth MOSFET MN2. A source of the third MOSFET MN1 is connected to a source of the fourth MOSFET MN2, and the gate of the third MOSFET MN1 is connected to the gate of the fourth MOSFET MN2. The gate of the third MOSFET MN1 is also connected to its source. The drain of the third MOSFET MN1 serves as the sixth terminal, the connection between the source of the third MOSFET MN1 and the source of the fourth MOSFET MN2 serves as the seventh terminal, and the drain of the fourth MOSFET MN2 serves as the eighth terminal.

The third MOSFET MN1 and the fourth MOSFET MN2 can both be negative channel-metal-oxide-semiconductor field-effect transistor (NMOS transistor). The first MOSFET MP1 and the second MOSFET MP2 are positive channel-metal-oxide-semiconductor field-effect transistor (PMOS transistor).

The first current mirror 14 and the second current mirror 15 can also be constructed using bipolar junction transistors, those skilled in the art can determine the specific structure of the first current mirror 14 and the second current mirror 15 based on actual conditions.

In the embodiment, the first current IREF1 and the second current IREF2 both can be supplied by an external current source, and the supply voltage VCC can also be provided by an external voltage source, without being overly limited herein.

Furthermore, as shown in FIG. 4, the first differential pair transistor 16 includes a fifth MOSFET MN3 and a sixth MOSFET MN4. A drain of the fifth MOSFET MN3 is connected to a drain of the sixth MOSFET MN4, the source of the fifth MOSFET MN3 is connected to a source of the sixth MOSFET MN4. A connection node between the drain of the fifth MOSFET MN3 and the drain of the sixth MOSFET MN4 serves as the ninth terminal, a connection node between the source of the fifth MOSFET MN3 and the source of the sixth MOSFET MN4 serves as the tenth terminal. A gate of the fifth MOSFET MN3 serves as the eleventh terminal, the gate of the sixth MOSFET MN4 serves as the twelfth terminal.

In the embodiment, the fifth MOSFET MN3 and the sixth MOSFET MN4 can both be configured as NMOS transistors, when any of the transistors, either the fifth MOSFET MN3 or the sixth MOSFET MN4 is conducting, the input terminal of the first Schmitt trigger 11 is pulled down.

Furthermore, as shown in FIG. 4, the second differential pair transistor 17 includes a seventh MOSFET MN5 and an eighth MOSFET MN6. A drain of the seventh MOSFET MN5 is connected to the drain of the eighth MOSFET MN6, and the source of the seventh MOSFET MN5 is connected to the source of the eighth MOSFET MN6, a connection node between the drain of the seventh MOSFET MN5 and the drain of the eighth MOSFET MN6 serves as the thirteenth terminal, and a connection node between the source of the seventh MOSFET MN5 and the source of the eighth MOSFET MN6 serves as the fourteenth terminal, a gate of the seventh MOSFET MN5 serves as the fifteenth terminal, and a gate of the eighth MOSFET MN6 serves as the sixteenth terminal.

In the embodiment, the seventh MOSFET MN5 and the eighth MOSFET MN6 can both be configured as NMOS transistors, when any of the transistors, either the seventh MOSFET MN5 or the eighth MOSFET MN6 is conducting, the input terminal of the first Schmitt trigger 11 is pulled down. When the first pulse signal output from the first terminal 241 is in a falling edge state, the falling edge monitoring module 4 outputs a third pulse signal to the seventh MOSFET MN5, causing the seventh MOSFET MN5 to conduct. When the first pulse signal output from the second terminal 242 is in a falling edge state, the falling edge monitoring module 4 outputs a third pulse signal to the eighth MOSFET MN6, causing the eighth MOSFET MN6 to conduct.

In some embodiments, as shown in FIG. 1, the falling edge monitoring module 4 includes two first monitoring units 41, one first monitoring unit 41 is connected to the first terminal 241 and the signal restoration module 1 respectively, while another first monitoring unit 41 is respectively connected to the second terminal 242 and the signal restoration module 1; when the first pulse signal output from the first terminal 241 is in a falling edge state, the first monitoring unit 41 connected to the first terminal 241 outputs a third pulse signal to the signal restoration module 1; when the first pulse signal output from the second terminal 242 is in a falling edge state, the first monitoring unit 41 connected to the second terminal 242 outputs a third pulse signal to the signal restoration module 1.

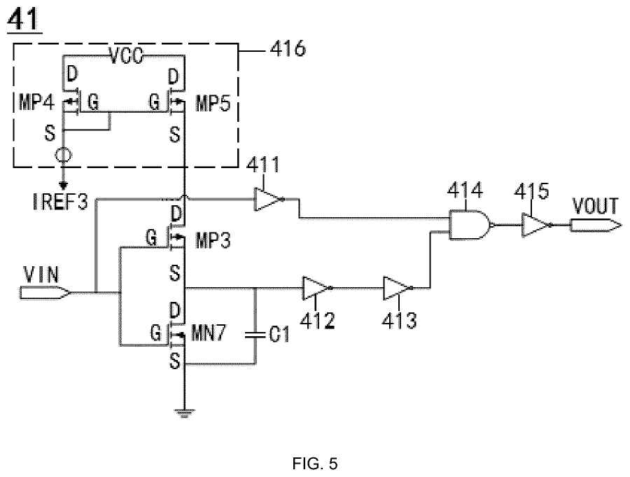

As shown in FIG. 5, the first monitoring unit 41 includes a third current mirror 416, a ninth MOSFET MP3, a tenth MOSFET MN7, a first capacitor C1, a second Schmitt trigger 412, a first NAND gate 414, a third inverter 411, a fourth inverter 413, and a fifth inverter 415.

As shown in FIG. 5, the third current mirror 416 includes a seventeenth terminal, an eighteenth terminal, and a nineteenth terminal, where the seventeenth terminal is connected to the third current IREF3 and the eighteenth terminal is connected to the supply voltage VCC; a drain of the ninth MOSFET MP3 is connected to the nineteenth terminal, and the gates of the ninth MOSFET MP3, the tenth MOSFET MN7, and the input terminal of the third inverter 411 are connected commonly, a source of the ninth MOSFET MP3 is connected to a drain of the tenth MOSFET MN7, and a source of the tenth MOSFET MN7 is grounded, an output terminal of the third inverter 411 is connected to a first input terminal of a first NAND gate 414; an input terminal of the second Schmitt trigger 412 is connected to the connection node between the source of the ninth MOSFET MP3 and the drain of the tenth MOSFET MN7, one terminal of the first capacitor C1 is connected to the input terminal of the second Schmitt trigger 412, and the other terminal of the first capacitor C1 is grounded. The output terminal of the second Schmitt trigger 412 is connected to the input terminal of the fourth inverter 413, and the output terminal of the fourth inverter 413 is connected to the second input terminal of the first NAND gate 414, the output terminal of the first NAND gate 414 is connected to the input terminal of the fifth inverter 415; the common connection of the gates of the ninth MOSFET MP3, the tenth MOSFET MN7, and the input terminal of the third inverter 411 is configured to receive the first pulse signal output from the modulation module 2, the output terminal of the fifth inverter 415 is configured to output the third pulse signal to the signal restoration module 1.

In the embodiment, the third inverter 411 of one first monitoring unit 41 is connected to the first terminal 241 of the modulation module 2, and the fifth inverter 415 of the first monitoring unit 41 is connected to the gate of the seventh MOSFET MN5; the third inverter 411 of the other first monitoring unit 41 is connected to the second terminal 242 of the modulation module 2, and the fifth inverter 415 of the first monitoring unit 41 is connected to the gate of the eighth MOSFET MN6.

When the first pulse signal output from the first terminal 241 of the modulation module 2 is a falling edge, the output terminal of the third inverter 411 in the first monitoring unit 41 connected to the first terminal 241 immediately outputs a high level, meaning that the first input terminal of the first NAND gate 414 receives a high level, at this time, the ninth MOSFET MP3 is in a conducting state, and the tenth MOSFET MN7 is in an off state. the first capacitor C1 begins to charge and, after a first time Tpulse, the first capacitor C1 becomes fully charged. At this point, the second input terminal of the first NAND gate 414 also receives a high level, therefore, after the first time Tpulse, the first NAND gate 414 outputs a high level, which is then inverted by the fifth inverter 415, consequently, the output terminal of the fifth inverter 415 outputs a third pulse signal with a pulse width of Tpulse to the seventh MOSFET MN5.

As can be seen, when the first pulse signal output from the first terminal 241 of the modulation module 2 is in a falling edge state, the output terminal of the fifth inverter 415 in the first monitoring unit 41 connected to the first terminal 241 outputs a third pulse signal with a pulse width of Tpulse, and the seventh MOSFET MN5 is conducted, pulling the input terminal of the first Schmitt trigger 11 down, then the output terminal of the second inverter 13 outputs the restored pulse width modulation signal.

Similarly, when the first pulse signal output from the second terminal 242 of the modulation module 2 is in a falling edge state, the output terminal of the third inverter 411 in the first monitoring unit 41 connected to the second terminal 242 immediately outputs a high level, meaning that the first input terminal of the first NAND gate 414 receives a high level, at this time, the ninth MOSFET MP3 is in a conducting state, and the tenth MOSFET MN7 is in an off state, the first capacitor C1 begins to charge and, after a first time Tpulse, the first capacitor C1 becomes fully charged, at this point, the second input terminal of the first NAND gate 414 also receives a high level, therefore, after the first time Tpulse, the first NAND gate 414 outputs a high level, which is then inverted by the fifth inverter 415, consequently, the output terminal of the fifth inverter 415 outputs a third pulse signal with a pulse width of Tpulse to the seventh MOSFET MN5.

As can be seen, when the first pulse signal output from the second terminal 242 of the modulation module 2 is in a falling edge state, the output terminal of the fifth inverter 415 in the first monitoring unit 41 connected to the second terminal 242 outputs a third pulse signal with a pulse width of Tpulse causing the eighth MOSFET MN6 to conduct, pulling the input terminal of the first Schmitt trigger 11 down, and the output terminal of the second inverter 13 outputs the restored pulse width modulation (PWM) signal.

Notably, based on the preceding discussion, the time at which the second input terminal of the first NAND gate 414 receives a high level is related to the first capacitor C1, specifically to a capacitance of the first capacitor C1. When the capacitance of the first capacitor C1 is large, the pulse width Tpulse is correspondingly wider, conversely, when the capacitance of the first capacitor C1 is small, the pulse width Tpulse is correspondingly narrower.

In the embodiment, the third current IREF3 can be provided by an external current source.

In the embodiment, when the fifth MOSFET MN3 and the sixth MOSFET MN4 are conducting, when the fifth MOSFET MN3 turns off and the sixth MOSFET MN4 slightly conducts, or when the sixth MOSFET MN4 turns off and the fifth MOSFET MN3 slightly conducts, the restored pulse width modulation signal output by the second inverter 13 can exhibit glitches (the specific situation of the generated glitches can be referred to in FIG. 2), however, since there are two first monitoring units 41, even if the fifth MOSFET MN3 slightly conducts or the sixth MOSFET MN4 slightly conducts, one of the seventh MOSFET MN5 or the eighth MOSFET MN6 remains in a conducting state, pulling the input terminal of the first Schmitt trigger 11 down, the second inverter 13 outputs the restored PWM signal, therefore, the configuration of the two first monitoring units 41 eliminates the glitches produced when the fifth MOSFET MN3 or the sixth MOSFET MN4 slightly conducts, further enhancing the reliability of the system.

As shown in FIG. 6, by comparing the waveform of different nodes in the isolated gate drive circuit of the present disclosure as shown in FIG. 6 with the waveform of different nodes in the prior isolated gate drive circuit as shown in FIG. 2, it is evident that the restored pulse width modulation signal output by the isolated gate drive circuit of the present disclosure does not contain glitches.

In some embodiments, as shown in FIG. 5, the third current mirror 416 includes an eleventh MOSFET MP4 and a twelfth MOSFET MP5; the drain of the eleventh MOSFET MP4 is connected to the drain of the twelfth MOSFET MP5, and the gate of the eleventh MOSFET MP4 is connected to the gate of the twelfth MOSFET MP5, the gate of the eleventh MOSFET MP4 is also connected to its source, the source of the eleventh MOSFET MP4 serves as the seventeenth terminal, the connection node between the drain of the eleventh MOSFET MP4 and the drain of the twelfth MOSFET MP5 serves as the eighteenth terminal, and the source of the twelfth MOSFET MP5 serves as the nineteenth terminal.

In some embodiments, as shown in FIG. 1, the modulation module 2 can include a second NAND gate 21, a sixth inverter 22, a seventh inverter 23, a second capacitor C2, a third capacitor C3, and a dual-output first comparator 24.

A first input terminal of the second NAND gate 21 is configured to receive the pulse width modulation signal, a second input terminal of the second NAND gate 21 is configured to receive the oscillation (OSC) signal, such as the oscillation signal output from a high-frequency oscillator, an output terminal of the second NAND gate 21 is connected to the input terminal of the sixth inverter 22 and the seventh inverter 23; an output terminal of the sixth inverter 22 is connected to one terminal of the second capacitor C2, an output terminal of the seventh inverter 23 is connected to one terminal of the third capacitor C3; the first input terminal of the first comparator 24 is connected to the other terminal of the second capacitor C2, and a second input terminal of the first comparator 24 is connected to the other terminal of the third capacitor C3, a first output terminal of the first comparator 24 serves as the first terminal 241, and a second output terminal of the first comparator 24 serves as the second terminal 242.

The first output terminal of the first comparator 24 is connected to the high-pass filter module 3, and also to the common connection to the third inverter 411, the gate of the ninth MOSFET MP3, and the gate of the tenth MOSFET MN7 in the first monitoring unit 41, which is connected to the first terminal 241; the second output terminal of the first comparator 24 is connected to the high-pass filter module 3 and also to the common connection of the third inverter 411, the gate of the ninth MOSFET MP3, and the gate of the tenth MOSFET MN7 in the first monitoring unit 41 connected to the second terminal 242.

In the embodiment, the pulse width modulation signal and the oscillation (OSC) signal are input to the second NAND gate 21, which outputs a signal to the sixth inverter 22 and the seventh inverter 23, the output terminals of the sixth inverter 22 and the seventh inverter 23 generate differential signals, which are further converted into a pair of narrow pulse signals through the second capacitor C2 and the third capacitor C3 (C2 and C3) acting as isolation capacitors), the pair of narrow pulse signals is input to the first comparator 24, the rail-to-rail differential pulse signal (the first pulse signal output from the first terminal 241) output from the first output terminal of the first comparator 24 is split into two paths: one path outputs to the high-pass filter module 3, which is filtered and then outputs a second pulse signal to the signal restoration module 1 (the gate of the fifth MOSFET MN3); another path outputs to the first monitoring unit 41 connected to the first terminal 241 (the common node connecting the third inverter 411, the gate of the ninth MOSFET MP3, and the gate of the tenth MOSFET MN7); the differential pulse signal output from the second output terminal of the first comparator 24 (the first pulse signal output from the second terminal 242) is split into two paths, one of the paths outputs to the high-pass filter module 3, where the signal is filtered and the resulting second pulse signal outputs to the signal restoration module 1 (the gate of the sixth MOSFET MN4), the other path outputs to the first monitoring unit 41 connected to the second terminal 242 (the common node connecting the third inverter 411, the gate of the ninth MOSFET MP3, and the gate of the tenth MOSFET MN7).

In some embodiments, as shown in FIG. 1, the high-pass filter module 3 can include a fourth capacitor C4, a fifth capacitor C5, a first resistor R1, a second resistor R2, a third resistor R3, and a fourth resistor R4.

One terminal of the fourth capacitor C4 is connected to the first output terminal of the first comparator 24, and the other terminal of the fourth capacitor C4 is connected to one terminal of the first resistor R1, with the other terminal of the first resistor R1 grounded, one terminal of the second resistor R2 is connected to the junction of the first resistor R1 and the fourth capacitor C4, and the other terminal of the second resistor R2 is connected to one terminal of the third resistor R3, the other terminal of the third resistor R3 is connected to one terminal of the fourth resistor R4, with the other terminal of the fourth resistor R4 grounded, one terminal of the fifth capacitor C5 is connected to the second output terminal of the first comparator 24, and the other terminal of the fifth capacitor C5 is connected to the junction of the third resistor R3 and the fourth resistor R4, the junction of the third resistor R3 and the second resistor R2 is connected to a reference voltage, the junction of the first resistor R1 and the second resistor R2 is connected to the gate of the fifth MOSFET MN3, and the junction of the third resistor R3 and the fourth resistor R4 is connected to the gate of the sixth MOSFET MN4.

In the embodiment, the first pulse signal output from the first output terminal of the first comparator 24 to the high-pass filter module 3 passes through the fourth capacitor C4 and is then output to the fifth MOSFET MN3. The first pulse signal output from the second output terminal of the first comparator 24 to the high-pass filter module 3 passes through the fifth capacitor C5 and is then output to the sixth MOSFET MN4.

In some embodiments, the present disclosure also provides a driver, including: a printed circuit board (PCB) and the isolated gate drive circuit as described above, the isolated gate drive circuit as described above is mounted on the printed circuit board.

It should be noted that the description of the above driver embodiment is similar to the description of the aforementioned isolated gate drive circuit embodiment, offering similar beneficial effects. For technical details not disclosed in the driver embodiment, please refer to the description of the isolated gate drive circuit embodiment for understanding.

Summarily, the present disclosure provides an isolated gate drive circuit and a driver, which have the following beneficial effects:

The isolated gate drive circuit, when restoring the pulse width modulation signal, also monitors the first pulse signals output from the first terminal 241 and the second terminal 242 of the modulation module 2 by the falling edge monitoring module 4, when the first pulse signals output from the first terminal 241 or the second terminal 242 of the modulation module 2 are in a falling edge state, the falling edge monitoring module 4 outputs a third pulse signal to the signal restoration module 1, enabling the signal restoration module 1 to output the restored pulse width modulation signal. It can be seen that in the first falling edge of the first pulse signal in the first cycle output by the modulation module 2, the falling edge monitoring module 4 can output the third pulse signal to the signal restoration module 1, allowing the signal restoration module 1 to quickly output the restored pulse width modulation signal in the first falling edge of the pulse signal within the first cycle output by the modulation module 2, thereby improving the reliability of the isolated gate drive circuit.

The embodiments described above are provided to illustrate the technical solutions of the present disclosure. While the description is specific and detailed, it should not be construed as limiting the scope of the patent of the present disclosure. It should be understood by those skilled in the art that, without departing from the conception of the present disclosure, the aforementioned technical features can be freely combined. Various modifications and improvements can also be made, all of which should be included within the protection scope of the present disclosure.

What is claimed is:

1. An isolated gate drive circuit, comprising:
a modulation module, comprising a first terminal and a second terminal; the first terminal is configured to output a first pulse signal, and the second terminal is configured to output a first pulse signal, wherein the first pulse signal output from the first terminal and the first pulse signal output from the second terminal are rail-to-rail differential pulse signals;
a high-pass filter module, connected to the first terminal and the second terminal respectively, and the high-pass filter module is configured to filter the first pulse signals output from the first terminal and the second terminal, and then output a second pulse signal;
a falling edge monitoring module, connected to the first terminal and the second terminal respectively, and the falling edge monitoring module is configured to output a third pulse signal when the first pulse signal output from the first terminal or the first pulse signal output from the second terminal is in a falling edge state;
a signal restoration module, connected to the high-pass filter module and the falling edge monitoring module respectively, and the signal restoration module is configured to quickly output a restored pulse width modulation signal based on the second pulse signal or the third pulse signal.

2. The isolated gate drive circuit according to claim 1, wherein the signal restoration module comprises: a first current mirror, a second current mirror, a first differential pair transistor, a second differential pair transistor, a first Schmitt trigger, a first inverter, and a second inverter;
the first current mirror comprises a third terminal, a fourth terminal, and a fifth terminal, wherein the third terminal is connected to a first current, and the fourth terminal is connected to a supply voltage;
the second current mirror comprises a sixth terminal, a seventh terminal, and an eighth terminal, wherein the sixth terminal is connected to a second current, and the seventh terminal is grounded;
the first differential pair transistor comprises a ninth terminal, a tenth terminal, an eleventh terminal, and a twelfth terminal, wherein the ninth terminal is connected to the fifth terminal, the tenth terminal is connected to the eighth terminal, the eleventh terminal is connected to the high-pass filter module, and the twelfth terminal is connected to the high-pass filter module;
the second differential pair transistor comprises a thirteenth terminal, a fourteenth terminal, a fifteenth terminal, and a sixteenth terminal, wherein the fourteenth terminal is grounded, the fifteenth terminal is connected to the falling edge monitoring module, and the sixteenth terminal is connected to the falling edge monitoring module;
an input terminal of the first Schmitt trigger is connected to a connection path between the fifth terminal and the ninth terminal, and input terminal of the first Schmitt trigger is connected to the thirteenth terminal; an output terminal of the first Schmitt trigger is connected to an input terminal of the first inverter, an output terminal of the first inverter is connected to an input terminal of the second inverter, and an output terminal of the second inverter outputs the restored pulse width modulation signal.

3. The isolated gate drive circuit according to claim 2, wherein the first current mirror comprises: a first MOSFET and a second MOSFET, wherein a drain of the first MOSFET is commonly connected to a drain of the second MOSFET, a source of the first MOSFET is connected to a gate of the first MOSFET, and the gate of the first MOSFET is also connected to a gate of the second MOSFET, wherein the source of the first MOSFET serves as the third terminal, a connection node between the drain of the first MOSFET and the drain of the second MOSFET serves as the fourth terminal, and the source of the second MOSFET serves as the fifth terminal;
the second current mirror comprises: a third MOSFET and a fourth MOSFET, wherein a source of the third MOSFET is connected to a source of the fourth MOSFET, a gate of the third MOSFET is connected to a gate of the fourth MOSFET, and the gate of the third MOSFET is also connected to the source of the third MOSFET, wherein a drain of the third MOSFET serves as the sixth terminal, a connection node between the source of the third MOSFET and the source of the fourth MOSFET serves as the seventh terminal, and a drain of the fourth MOSFET serves as the eighth terminal.

4. The isolated gate drive circuit according to claim 3, wherein the first differential pair transistor comprises a fifth MOSFET and a sixth MOSFET;
a drain of the fifth MOSFET is connected to a drain of the sixth MOSFET, a source of the fifth MOSFET is connected to a source of the sixth MOSFET, a connection node between the drain of the fifth MOSFET and the drain of the sixth MOSFET serves as the ninth terminal, a connection node between the source of the fifth MOSFET and the source of the sixth MOSFET serves as the tenth terminal, a gate of the fifth MOSFET serves as the eleventh terminal, and a gate of the sixth MOSFET serves as the twelfth terminal.

5. The isolated gate drive circuit according to claim 4, wherein the second differential pair transistor comprises a seventh MOSFET and an eighth MOSFET;
a drain of the seventh MOSFET is connected to a drain of the eighth MOSFET, a source of the seventh MOSFET is connected to a source of the eighth MOSFET, a connection node between the drain of the seventh MOSFET and the drain of the eighth MOSFET serves as the thirteenth terminal, a connection node between the source of the seventh MOSFET and the source of the eighth MOSFET serves as the fourteenth terminal, a gate of the seventh MOSFET serves as the fifteenth terminal, and a gate of the eighth MOSFET serves as the sixteenth terminal.

6. The isolated gate drive circuit according to claim 1, wherein the falling edge monitoring module comprises:
two first monitoring units, wherein one first monitoring unit is respectively connected to the first terminal and the signal restoration module, and another first monitoring unit is respectively connected to the second terminal and the signal restoration module;
wherein, when the first pulse signal output from the first terminal is in a falling edge state, the first monitoring unit connected to the first terminal is configured to output the third pulse signal to the signal restoration module; and when the first pulse signal output from the second terminal is in a falling edge state, the first monitoring unit connected to the second terminal is configured to output the third pulse signal to the signal restoration module.

7. The isolated gate drive circuit according to claim 6, wherein the first monitoring unit comprises: a third current mirror, a ninth MOSFET, a tenth MOSFET, a first capacitor, a second Schmitt trigger, a first NAND gate, a third inverter, a fourth inverter, and a fifth inverter;
the third current mirror comprises a seventeenth terminal, an eighteenth terminal, and a nineteenth terminal, wherein the seventeenth terminal is connected to the second current, and the eighteenth terminal is connected to the supply voltage;
a drain of the ninth MOSFET is connected to the nineteenth terminal; a gate of the ninth MOSFET, a gate of the tenth MOSFET, and an input terminal of the third inverter are commonly connected, a source of the ninth MOSFET is connected to a drain of the tenth MOSFET, a source of the tenth MOSFET is grounded, and an output terminal of the third inverter is connected to a first input terminal of the first NAND gate;
an input terminal of the second Schmitt trigger is connected to a connection path between a source of the ninth MOSFET and a drain of the tenth MOSFET; one terminal of the first capacitor is connected to the input terminal of the second Schmitt trigger, and another terminal of the first capacitor is grounded; and an output terminal of the second Schmitt trigger is connected to an input terminal of the fourth inverter, an output terminal of the fourth inverter is connected to a second input terminal of the first NAND gate, and an output terminal of the first NAND gate is connected to an input terminal of the fifth inverter;
wherein a common connection node of the gate of the ninth MOSFET, the gate of the tenth MOSFET, and the input terminal of the third inverter is configured to receive the first pulse signal output from the modulation module, and an output terminal of the fifth inverter is configured to output the third pulse signal to the signal restoration module.

8. The isolated gate drive circuit according to claim 7, wherein the third current mirror comprises: an eleventh MOSFET and a twelfth MOSFET;
a drain of the eleventh MOSFET is connected to a drain of the twelfth MOSFET, a gate of the eleventh MOSFET is connected to a gate of the twelfth MOSFET, and the gate of the eleventh MOSFET is also connected to a source of the eleventh MOSFET, wherein the source of the eleventh MOSFET serves as the seventeenth terminal, a connection node between the drain of the eleventh MOSFET and the drain of the twelfth MOSFET serves as the eighteenth terminal, and a source of the twelfth MOSFET serves as the nineteenth terminal.

9. The isolated gate drive circuit according to claim 8, wherein the modulation module comprises: a second NAND gate, a sixth inverter, a seventh inverter, a second capacitor, a third capacitor, and a first comparator with dual outputs;
a first input terminal of the second NAND gate is configured to receive the pulse width modulation signal, a second input terminal of the second NAND gate is configured to receive an oscillation signal, and an output terminal of the second NAND gate is connected to an input terminal of the sixth inverter and an input terminal of the seventh inverter, respectively;
an output terminal of the sixth inverter is connected to one terminal of the second capacitor, and an output terminal of the seventh inverter is connected to one terminal of the third capacitor;
a first input terminal of the first comparator is connected to another terminal of the second capacitor, and a second input terminal of the first comparator is connected to another terminal of the third capacitor, wherein a first output terminal of the first comparator serves as the first terminal, and a second output terminal of the first comparator serves as the second terminal.

10. A driver, comprising: a printed circuit board and the isolated gate drive circuit according to claim 1, wherein the isolated gate drive circuit according to claim 1 is mounted on the printed circuit board.
